(19) United States
(12) Patent Application Publication
(10) Pub. No.: US 2009/0093122 A1
(43) Pub. Date: Apr. 9, 2009

(54) Method For Producing Group III-V Nitride Semiconductor Substrate

(75) Inventors: Kazumasa Ueda, Ibaraki (JP); Naohiro Nishikawa, Chiba (JP); Kenji Kasahara, Ibaraki (JP)

Correspondence Address: FITCH, EVEN, TABIN & FLANNERY, P. O. BOX 18415, WASHINGTON, DC, 20036, US

(73) Assignee: SUMITOMO CHEMICAL COMPANY LIMITED, Tokyo (JP)

(21) Appl. No.: 12/224,984

(22) PCT Filed: Mar. 8, 2007
(86) PCT No.: PCT/JP2007/055161

§ 371 Date: Sep. 11, 2008

(30) Foreign Application Priority Data
Mar. 13, 2006 (JP) 2006-067012

(51) Int. Cl. H01L 21/32

(52) U.S. Cl. 438/701; 257/E21.23

(57) ABSTRACT

The present invention provides a method for producing a group III-V nitride semiconductor substrate. The method for producing a group III-V nitride semiconductor substrate comprises the steps of (I-1) to (I-6): (I-1) placing inorganic particles on a template, (I-2) dry-etching the template by using the inorganic particles as an etching mask, to form convexes on the template, (I-3) forming a coating film for an epitaxial growth mask on the template, (I-4) removing the inorganic particles to form an exposed surface of the template, (I-5) growing a group III-V nitride semiconductor on the exposed surface of the template, and (I-6) separating the group III-V nitride semiconductor from the template.

### TECHNICAL FIELD

The present invention relates to a method for producing a group III-V nitride semiconductor substrate.

### BACKGROUND ART

A group III-V nitride semiconductor represented by the formula InₓGa_{y}Al_{z}N (wherein, 0≦x≦1, 0≦y≦1, 0≦z≦1, x+y+z=1) is used in semiconductor light emitting devices such as ultraviolet, blue or green light emitting diode devices, or ultraviolet, blue or green laser diode devices, and the like. Semiconductor light emitting devices are applied to displays.

Since it is hard to produce a group III-V nitride semiconductor by bulk crystal growth technique, a method for producing a group III-V nitride semiconductor free standing substrate is not put into practical use. Thus, a group III-V nitride semiconductor substrate is produced by a method of epitaxially growing a group III-V nitride semiconductor on a sapphire substrate by metal organic vapor phase epitaxy (MOVPE) and the like.

The sapphire substrate, however, is different in lattice constant and thermal expansion coefficient from the group III-V nitride semiconductor, thus, in a method using the sapphire substrate, dislocation of high density is introduced into, warping occurs and cracking is generated in the resultant group III-V nitride semiconductor substrate, in some cases.

Further, there is a proposed method for producing a group III-V nitride semiconductor substrate, including growing a group III-V nitride semiconductor on a template such as sapphire, and separating the group III-V nitride semiconductor from the template. Examples of the method include a method in which a GaN layer is grown on a sapphire substrate by hydride vapor phase epitaxy (HVPE), and the sapphire substrate is mechanically removed by polishing, or a method in which a GaN layer is grown on a sapphire substrate by HVPE, and the GaN layer is peeled by irradiation with a laser pulse. JP-A No. 2000-12900 discloses a method in which a GaAs substrate is used as a substrate which can be removed easily, GaN is grown on the GaAs substrate by HVPE, thereafter, the GaAs substrate is removed by dissolution with aqua regalis. Further, JP-A No. 2004-55799 discloses a method in which a sapphire substrate is subjected to concavo-convex processing, a SiO₂ film is formed on the side surface and top surface of the convex, then, GaN is grown, then, cooled to cause peeling off, to obtain a group III-V nitride semiconductor substrate.

However, none of these methods are put into practical use, and there is a need for a method of producing a group III-V nitride semiconductor substrate.

### DISCLOSURE OF THE INVENTION

The present invention has an object of providing a method for producing a group III-V nitride semiconductor substrate. The present inventors have studied a method for producing a group III-V nitride semiconductor substrate and resultantly completed the present invention.

That is, the present invention provides a method for producing a group III-V nitride semiconductor substrate comprising the steps of (I-1) to (I-6):

(I-1) placing inorganic particles on a template,

(I-2) dry-etching the template by using the inorganic particles as an etching mask, to form convexes on the template,

(I-3) forming a coating film for an epitaxial growth mask on the template,

(I-4) removing the inorganic particles to form an exposed surface of the template,

(I-5) growing a group III-V nitride semiconductor on the exposed surface of the template, and

(I-6) separating the group III-V nitride semiconductor from the template.

Further, the present invention provides a method for producing a group III-V nitride semiconductor substrate comprising the steps of (II-1) to (II-7):

(II-1) placing inorganic particles on a template,

(II-2) dry-etching the template by using the inorganic particles as an etching mask, to form convexes on the template,

(II-3) removing the inorganic particles,

(II-4) forming a coating film for an epitaxial growth mask on the template,

(II-5) removing the coating film at the top of the convexes, to form an exposed surface of the template,

(II-6) growing a group III-V nitride semiconductor on the exposed surface of the template, and

(II-7) separating the group III-V nitride semiconductor from the template.

### BRIEF DESCRIPTION OF DRAWINGS

FIG. 1 shows steps in the production method 1 of a group III-V nitride semiconductor substrate of the present invention.

FIG. 2 shows steps in the production method 2 of a group III-V nitride semiconductor substrate of the present invention.

### EXPLANATION OF MARKS

1: template

1A: surface of template

1B: convex

1C: valley part

2: inorganic particle

3, 13: coating film

4: growth mask

5: group III-V nitride semiconductor layer

### MODE OF CARRYING OUT THE INVENTION

### Method 1 for Producing a Group III-V Nitride Semiconductor Substrate

The method 1 for producing a group III-V nitride semiconductor substrate of the present invention includes the steps of (I-1) to (I-6).

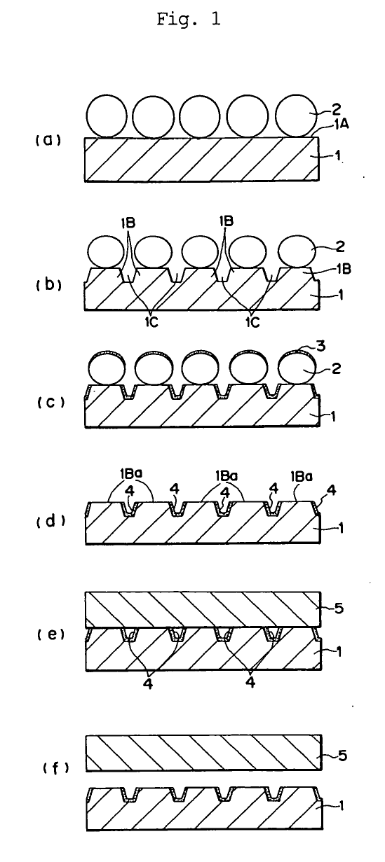

In the step (I-1), inorganic particles are placed on a template. For example, as shown in FIG. 1 (a), a template 1 is prepared, and inorganic particles 2 are placed on the surface 1A of the template 1.

The template is composed of, for example, sapphire, SiC, Si, MgAl₂O₄, LiTaO₃, ZrB₂ or CrB₂, and preferable from the standpoints of reactivity with a group III-V nitride semiconductor, difference in thermal expansion coefficient and stability at high temperatures are sapphire, SiC and Si, and more preferable is sapphire.

The inorganic particles are composed of, for example, an oxide, nitride, carbide, boride, sulfide, selenide or metal. The content thereof is usually not less than 50% by weight, preferably not less than 90% by weight, more preferably not less than 95% by weight with respect to the inorganic particles. Examples of the oxide include silica, alumina, zirconia, titania, ceria, zinc oxide, tin oxide, and yttrium aluminum garnet (YAG). Examples of the nitride include silicon nitride and boron nitride. Examples of the carbide include silicon carbide (SiC), boron carbide, diamond, graphite and fullerenes. Examples of the boride include zirconium boride (ZrB₂) and chromium boride (CrB₂). Examples of the sulfide include zinc sulfide, cadmium sulfide, calcium sulfide and strontium sulfide. Examples of the selenide include zinc selenide and cadmium selenide. In the oxide, nitride, carbide, boride, sulfide and selenide, elements contained therein may be partially substituted by other elements, and examples thereof include silicate or aluminate phosphor containing cerium or europium as an activator. Examples of the metal include silicon (Si), nickel (Ni), tungsten (W), tantalum (Ta), chromium (Cr), titanium (Ti), magnesium (Mg), calcium (Ca), aluminum (Al), gold (Au), silver (Ag) and zinc (Zn).

The inorganic particle may also be a material which can be converted to the oxide, nitride, carbide, boride, sulfide, selenide or metal described above on heat treatment, and for example, may be silicone. Silicone is a polymer having a structure in which an organic bond of Si—O—Si is formed as a backbone and organic substituents attach to the Si portions, and it is converted to silica when heated at about 500° C.

The inorganic particles may be used singly, or in admixture thereof. The inorganic particles may be, for example, coated particles obtained by coating inorganic particles made of a nitride with an oxide. Of them, the inorganic particles are preferably made of an oxide, more preferably silica.

The inorganic particles may be in the form of sphere (the cross-section is, for example, circle or ellipse), plate (aspect ratio L/T of length L to thickness T is 1.5 to 100), needle (for example, ratio L/W of length L to width W is 1.5 to 100), or no regular shape (including particles of various shapes, revealing totally irregular shapes), and particles in the form of sphere are preferable. Thus, the inorganic particle is more preferably spherical silica.

The inorganic particles have an average particle diameter of usually 5 nm to 50 μm, preferably 10 nm to 10 μm. When the average particle diameter is not less than 5 nm, a dry etching step described later can be carried out for a longer period of time, and deeper etching of the template is easy. When the average particle diameter is not more than 50 μm, distance between convexes is smaller in a step of growing a group III-V nitride semiconductor layer described later, thus, it becomes easy to grow them integrally. Within the above-described average particle diameter range, inorganic particles of different particle sizes may be mixed. The average particle diameter is a volume-average particle diameter measured by a centrifugal sedimentation. The average particle diameter may be measured by other measuring method than the centrifugal sedimentation, for example, a dynamic light scattering, Coulter counter, laser diffraction, or electron microscope. In this case, the measured value may be calibrated to conversion into volume-average particle diameter measured by a centrifugal sedimentation. For example, the average particle diameter of the standard particle is measured by a centrifugal sedimentation and other particle size measuring method, and a correlation coefficient thereof is calculated. The correlation coefficient is preferably obtained by calculating correlation coefficient with respect to volume-average particle diameter measured by a centrifugal sedimentation and making a calibration curve, for a plurality of standard particles of different particle sizes. If a calibration curve is used, the volume-average particle diameter is obtained from the average particle diameter obtained by other measuring method than the centrifugal sedimentation.

Placement may be advantageously carried out by, for example, a method of dipping a template in a slurry containing inorganic particles and a medium, or a method of coating or spraying a slurry on a template, then, drying.

Examples of the medium include water, methanol, ethanol, isopropanol, n-butanol, ethylene glycol, dimethylacetamide, methyl ethyl ketone and methyl isobutyl ketone, and preferably, water.

Coating is preferably carried out by spin coating. According to this method, inorganic particles can be placed with uniform density on a template. Drying may be advantageously carried out using a spinner.

The coverage of inorganic particles with respect to a template is usually 1% to 95%, preferably 30% to 95%, more preferably 50% to 95%. When not less than 1%, a group III-V nitride semiconductor layer is easily peeled from a template in a post step. Inorganic particles placed on a template may take a structure containing any number of layers, and single layer structure, that is, particle monolayer structure is preferable. The coverage may be advantageously measured by using a scanning electron microscope (SEM), and for example, may be advantageously calculated according to the following formula, from particle number P in the measurement visual field (area S) and particle average particle diameter d, when the surface 1A of the template 1 carrying inorganic particles 2 placed thereon is observed from upper side, in FIG. 1 (a).

Coverage (%)=((d/2)²×π·P·100)/S

In the step (I-2), a template is dry-etched by using inorganic particles as an etching mask, to form convexes on the template. For example, as shown in FIG. 1 (b), the template 1 is dry-etched by using the inorganic particles 2 as a mask, convexes 1B corresponding to the inorganic particles 2 are formed on the template 1.

Dry-etching may be advantageously carried out using, for example, an ECR dry etching apparatus or ICP dry etching apparatus. Dry etching is carried out usually under conditions whereby the height of the convex is 10 nm to 5 μm, preferably 30 nm to 3 μm.

In the step (I-3), a coating film for an epitaxial growth mask is formed on a template. For example, as shown in FIG. 1 (c), a coating film 3 for an epitaxial growth mask is formed on a template 1, thus, the surfaces of valley parts between the convexes 1B and the exposed surfaces of the inorganic particles 2 are coated with the coating film 3.

The coating film may be advantageously composed of a material which prevents epitaxial growth of a group III-V nitride semiconductor, and for example, composed of silicon dioxide (SiO₂) or silicon nitride (SiNₓ).

Formation may be, for example, advantageously carried out by CVD or evaporating coating under conditions whereby the template is coated.

(I-4) Inorganic particles are removed to form an exposed surface of a template. For example, as shown in FIG. 1 (d), inorganic particles 2 are removed to expose a template 1 at the top of the convex 1B and simultaneously to leave the coating film 3 on the surface of each valley part 1C formed between the convexes 1B, thereby forming a growth mask 4.

Removal may be advantageously carried out, for example, by a physical method using a brash roll cleaner or polisher. When the inorganic particles and coating film can be selectively etched, removal may be carried out by wet etching.

(I-5) A group III-V nitride semiconductor is epitaxially grown on the exposed surface of the template. For example, as shown in FIGS. 1 (d) and (e), group III-V nitride semiconductors are grown on the tops 1Ba of the convexes 1B not coated with the growth mask 4, and the grown group III-V nitride semiconductors are integrated to form a group III-V nitride semiconductor layer 5.

The group III-V nitride semiconductor layer is usually represented by InₓGa_{y}Al_{z}N (wherein, 0≦x≦1, 0≦y≦1, 0≦z≦1, x+y+z=1).

Epitaxial growth may be advantageously carried out, for example, by metal organic vapor phase epitaxy (MOVPE), halide vapor phase epitaxy (HVPE) or molecular beam epitaxy (MBE).

In MOVPE, the following materials may be advantageously used. Examples of the group III material include trialkylgallium of the formula: R₁R₂R₃Ga (R₁, R₂ and R₃ represent a lower alkyl group) such as trimethyl gallium [(CH₃)₃Ga, hereinafter, referred to as “TMG”] and triethyl gallium [(C₂H₅)₃Ga, “TEG”]; trialkyl aluminum of the formula: R₁R₂R₃Al (R₁, R₂ and R₃ represent a lower alkyl group) such as trimethyl aluminum [(CH₃)₃Al, “TMA”], triethyl aluminum [(C₂H₅)₃Al, “TEA”] and triisobutyl aluminum [(i-C₄H₉)₃Al]; trimethylamine alane [(CH₃)₃N:AlH₃]; trialkyl indium of the formula: R₁R₂R₃In (R₁, R₂ and R₃ represent a lower alkyl group) such as trimethyl indium [(CH₃)₃In, “TMI”] and triethyl indium [(C₂H₅)₃In]; those obtained by substituting one or two alkyl groups of trialkyl indium with a halogen atom such as diethyl indium chloride [(C₂H₅)₂InCl]; and indium halide of the formula: InX (X is a halogen atom) such as indium chloride [InCl]. These may be used singly or in admixture. Of these group III materials, preferable as the gallium source is TMG, as the aluminum source is TMA, and as the indium source is TMI. Examples of the group V material include ammonia, hydrazine, methylhydrazine, 1,1-dimethylhydrazine, 1,2-dimethylhydrazine, t-butylamine, ethylenediamine and the like. These can be used singly or in admixture of any combination. Of these materials, ammonia and hydrazine are suitable due to little pollution with carbon in a semiconductor because of no inclusion of a carbon atom in the molecule, and ammonia is more suitable from the standpoint of easy availability of a product of high purity. In MOVPE, nitrogen, hydrogen, argon and helium, preferably hydrogen and helium may be advantageously used as an atmospheric gas in growing and a carrier gas for organometal material. These may be advantageously used singly or in admixture. In MOVPE, it is usual that a reaction gas is introduced in a reactor to grow a group III-V nitride semiconductor layer on a template carrying thereon a growth mask formed. The reactor is equipped with a material feeding line for feeding a material gas from a material feeding apparatus into the reactor, and in the reactor, a susceptor for heating a template is provided. The susceptor usually has a structure capable of rotating by a rotation apparatus, for uniformly growing a nitride semiconductor layer. In the susceptor, a heating apparatus such as an infrared lamp and the like is provided for heating the susceptor. By this heating, a material gas fed into the reactor through a material feeding line is thermally decomposed on a growing substrate, and a desired compound is grown in a gas phase on the template. An unreacted material gas in the material gas fed into the reactor is discharged into outside of the reactor through a discharge line, and fed to a discharge gas treatment apparatus.

In HVPE, the following materials may be advantageously used. Examples of the group III material include a gallium chloride gas generated by reacting gallium metal with a hydrogen chloride gas, and an indium chloride gas generated by reacting indium metal with a hydrogen chloride gas at high temperature. As the group V material, for example, ammonia is mentioned. Examples of the carrier gas include nitrogen, hydrogen, argon and helium, preferably, hydrogen and helium. These may be advantageously used singly or in admixture. In HVPE, it may be advantageous that these material gases are introduced into a reactor and a group III-V nitride semiconductor layer is grown to desired thickness on the template.

In MBE, the following materials may be advantageously used. Examples of the group III material include metals of gallium, aluminum and indium. Examples of the group V material include nitrogen and ammonia. Also in MBE, these material gases may be advantageously introduced into a reactor to grow a group III-V nitride semiconductor layer.

In epitaxial growth, it is preferable that a void (air gap) is formed between a template and a group III-V nitride semiconductor layer, and for example, as shown in FIGS. 1 (b) and (e), it is preferable that a group III-V nitride semiconductor layer 5 is grown so as to form a void in each valley part 1C of a template 1. When a void is formed, it is easier to separate a group III-V nitride semiconductor layer from a template.

In the step (I-6), a group III-V nitride semiconductor is separated from a template. For example, as shown in FIG. 1 (f), a group III-V nitride semiconductor layer 5 is separated from a template 1, to obtain a free standing substrate composed of the group III-V nitride semiconductor layer 5.

Separation may be advantageously carried out by a method of mechanically peeling off a template from a group III-V nitride semiconductor layer by applied stress, and the stress may be any of internal stress and external stress.

Separation may be advantageously carried out by a method, for example, of applying internal stress and/or external stress at an interface between a template and a group III-V nitride semiconductor layer. By applying internal stress and/or external stress at an interface, a template can be separated (peeled) easily from a group III-V nitride semiconductor layer.

Examples of the method using internal stress include a method in which a group III-V nitride semiconductor layer is grown, then, a template is spontaneously peeled by stress based on the difference in thermal expansion coefficient between the group III-V nitride semiconductor layer and the template. Typically, it may be advantageously carried out by cooling from the growth temperature of the group III-V nitride semiconductor layer to room temperature, by cooling from room temperature to lower temperature with a low temperature medium (liquid nitrogen and the like), or by heating from room temperature, then, cooling down to lower temperature with a low temperature medium (liquid nitrogen and the like).

Examples of the method using external stress include a method in which either a group III-V nitride semiconductor layer or a template is fixed, and load is applied to another one.

### Method 2 for Producing a Group III-V Nitride Semiconductor Substrate

The method 2 for producing a group III-V nitride semiconductor substrate of the present invention includes the steps of (II-1) to (II-7).

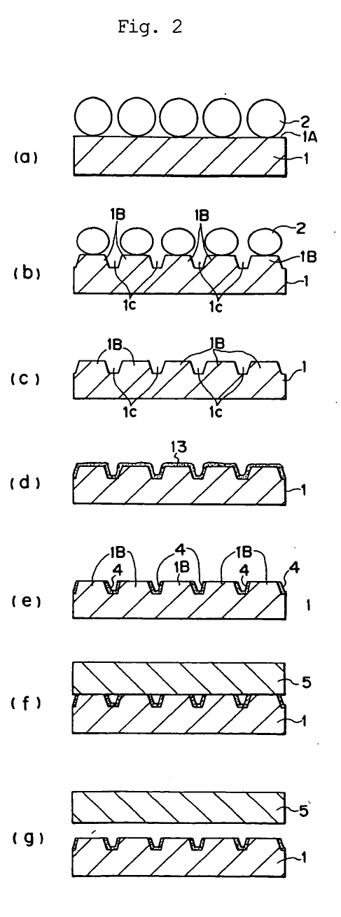

In the step (II-1), inorganic particles are placed on a template. For example, as shown in FIG. 2 (a), a template 1 is prepared, and inorganic particles 2 are placed on the surface 1A of the template 1. As the template and inorganic particles, the same matters as described in the step (I-1) may be advantageously used, and also placement may be advantageously carried by the same manner as described in the step (I-1).

In the step (II-2), a template is dry-etched by using inorganic particles as an etching mask, to form convexes on the template. For example, as shown in FIG. 2 (b), a template 1 is dry-etched using inorganic particles 2 as a mask, convexes 1B corresponding to the inorganic particles 2 are formed on the template 1. Dry-etching may be advantageously carried by the same manner as described in the step (I-2).

In the step (II-3), inorganic particles are removed. For example, as shown in FIGS. 2 (b) and (c), inorganic particles 2 are removed to form convexes 1B, obtaining a template 1 having valley parts 1C between the convexes 1B. Removal may be advantageously carried out, for example, by a physical method using a brash roll cleaner or polisher.

In the step (II-4), a coating film for an epitaxial growth mask is formed on a template. For example, as shown in FIG. 2 (d), a coating film 13 for an epitaxial growth mask is formed on a template 1. In FIG. 2 (d), the coating film 13 covers the whole surface of the template 1 in the irregular condition, thus, covers the surfaces of the valley parts 1C between the convexes 1B and the tops of the convexes 1B. For coating, the same matters as described in the step (I-3) may be advantageously used, and formation may be advantageously carried out by the same manner as described in the step (I-3).

In the step (II-5), the coating films at the tops of the convexes are removed to form exposed surfaces of the template. For example, as shown in FIG. 2 (e), epitaxial growth masks 4 are formed leaving the coating films 13 on the surfaces of the valley parts 1C between the convexes 1B, while other coating films are removed. Removal may be advantageously carried out, for example, by polishing.

In the step (II-6), a group III-V nitride semiconductor is grown on exposed surfaces of a template. For example, as shown in FIGS. 2 (e) and (f), group III-V nitride semiconductors are grown on the tops 1Ba of the convexes 1B not coated with an epitaxial growth mask 4, and the grown group III-V nitride semiconductors are integrated to form a group III-V nitride semiconductor layer 5.

In the step (II-7), a group III-V nitride semiconductor is separated from a template. For example, as shown in FIG. 2 (g), a group III-V nitride semiconductor layer 5 is separated from a template 1, to obtain a free standing substrate composed of the group III-V nitride semiconductor layer 5. Separation may be advantageously carried out by the same manner as described in the step (I-6).

### EXAMPLES

The present invention is described in more detail by following Examples, which should not be construed as a limitation upon the scope of the present invention.

### Example 1

As a template, a mirror-polished c-plane sapphire substrate was used. As inorganic particles, silica particles in the form of sphere (manufactured by Ube Nitto Kasei Co., Ltd., HIPRESICA (trade name), average particle diameter: 3 μm) were used, and these were dispersed in ethanol to give a 8% by weight slurry to be used. The slurry was coated on the sapphire substrate on a suspended spinner, then, the spinner was rotated at 500 rpm for 10 seconds, subsequently, at 2500 rpm for 40 seconds to dry the sapphire substrate. The coverage of the silica particles on the sapphire substrate was 87%.

The sapphire substrate was dry-etched to a depth of 0.35 μm, to form convexes corresponding to the shape of the silica particle on the surface of the sapphire substrate. Dry-etching was carried out by using an ICP dry etching apparatus under conditions of a substrate bias power of 300 W, an ICP power of 800 W, a pressure of 2 Pa, a chlorine gas rate of 32 sccm, a boron trichloride gas rate of 48 sccm, an argon gas rate of 190 sccm and a treatment time of 5 minutes.

Under conditions of adhesion of the silica particles to the sapphire substrate, a silicon dioxide (SiO₂) film was formed with a thickness of 2000 Å on the sapphire substrate by evaporating coating.

SiO₂ on the convexes of the sapphire substrate was removed together with the silica particles by a cotton applicator.

A group III-V nitride semiconductor layer was epitaxially grown on the sapphire substrate. In epitaxial growth, a GaN buffer layer having a thickness of 500 Å was grown by feeding a carrier gas, ammonia and TMG, at a pressure of 1 atm and a susceptor temperature of 485° C. by MOVPE using hydrogen as the carrier gas. The susceptor temperature was set at 900° C., then, a carrier gas, ammonia and TMG were fed to form an undoped GaN layer. The susceptor temperature was set at 1040° C. and the reactor pressure was lowered to ¼ atmospheric pressure, and a carrier gas, ammonia and TMG were fed to form an undoped GaN layer. The undoped GaN layer was grown to 20 μm, then, cooled from a growth temperature of 1040° C. down to room temperature slowly. By cooling, peeling off occurred on an interface of the sapphire substrate. The sapphire substrate was separated, to obtain a group III-V nitride semiconductor free standing substrate (GaN single crystal, thickness: 20 μm).

### Example 2

As a template, a sapphire substrate prepared by mirror-polishing the C-plane of sapphire was used. As inorganic particles, silica particles in the form of sphere (manufactured by Ube Nitto Kasei Co., Ltd., HIPRESICA (trade name), average particle diameter: 1 μm) were used, and these were dispersed in ethanol to give a 8% by weight slurry to be used. The slurry was coated on the sapphire substrate on a suspended spinner, then, the spinner was rotated at 500 rpm for 10 seconds, subsequently, at 2500 rpm for 40 seconds to dry the sapphire substrate. The coverage of the silica particles on the sapphire substrate was 83%.

The sapphire substrate was dry-etched to a depth of 0.21 μm, to form convexes corresponding to the shape of the silica particle on the surface of the sapphire substrate. Dry-etching was carried out by using an ICP dry etching apparatus under conditions of a substrate bias power of 300 W, an ICP power of 800 W, a pressure of 2 Pa, a chlorine gas rate of 32 sccm, a boron trichloride gas rate of 48 sccm, an argon gas rate of 190 sccm and a treatment time of 3 minutes.

Under conditions of adhesion of the silica particles to the sapphire substrate, a silicon dioxide (SiO₂) film was formed with a thickness of 2000 Å on the sapphire substrate by evaporating coating.

SiO₂ on the convexes of the sapphire substrate was removed together with the silica particles by a cotton applicator.

Subsequently, a group III-V nitride semiconductor layer was epitaxially grown on the sapphire substrate in the same manner as in Example 1.

The undoped GaN layer was grown to 20 μm, then, cooled from a growth temperature of 1040° C. down to room temperature slowly. By cooling, peeling off occurred on an interface of the sapphire substrate. The sapphire substrate was separated, to obtain a group III-V nitride semiconductor free standing substrate (GaN single crystal, thickness: 20 μm).

### Example 3

As a template, a sapphire substrate prepared by mirror-polishing the C-plane of sapphire was used. As inorganic particles, silica particles in the form of sphere contained in colloidal silica (manufactured by Nippon Shokubai Co., Ltd., SEAHOSTER KE-W50 (trade name), average particle diameter: 550 nm, water solvent) were used. The sapphire substrate was set on a spinner, and a slurry diluted to 16% by weight was dropped while rotating the spinner at 800 rpm, further, the spinner was rotated at 8000 rpm for 40 seconds to dry the sapphire substrate. The coverage of the silica particles on the sapphire substrate was 92%.

The sapphire substrate was dry-etched to a depth of 0.1 μm, to form convexes corresponding to the shape of the silica particle on the surface of the sapphire substrate. Dry-etching was carried out by using an ICP dry etching apparatus under conditions of a substrate bias power of 300 W, an ICP power of 800 W, a pressure of 2 Pa, a chlorine gas rate of 32 sccm, a boron trichloride gas rate of 48 sccm, an argon gas rate of 190 sccm and a treatment time of 1.5 minutes.

Under conditions of adhesion of the silica particles to the sapphire substrate, a silicon dioxide (SiO₂) film was formed with a thickness of 2000 Å on the sapphire substrate by evaporating coating.

SiO₂ on the convexes of the sapphire substrate was removed together with the silica particles by a cotton applicator.

Subsequently, a group III-V nitride semiconductor layer was epitaxially grown on the sapphire substrate in the same manner as in Example 1.

The undoped GaN layer was grown to 20 μm, then, cooled from a growth temperature of 1040° C. down to room temperature slowly. By cooling, peeling off occurred on an interface of the sapphire substrate. The sapphire substrate was separated, to obtain a group III-V nitride semiconductor free standing substrate (GaN single crystal, thickness: 20 μm).

### Comparative Example 1

A sapphire substrate as a template was not processed, and a group III-V nitride semiconductor layer was epitaxially grown on the un-processed sapphire substrate in the same manner as in Example 1.

The undoped GaN layer was grown to 20 μm, then, cooled from a growth temperature of 1040° C. down to room temperature slowly. No peeling off occurred on an interface between the GaN layer and the sapphire substrate.

Further, it was continued to grow the undoped GaN layer up to 45 μm, then, it was cooled from a growth temperature of 1040° C. down to room temperature slowly. In this cooling, no peeling off occurred on an interface between the GaN layer and the sapphire substrate, and both the GaN layer and the sapphire substrate were cracked.

### INDUSTRIAL APPLICABILITY

According to the production method of the present invention, a group III-V nitride semiconductor free standing substrate is obtained easily.

1. A method for producing a group III-V nitride semiconductor substrate comprising the steps of (I-1) to (I-6):
(I-1) placing inorganic particles on a template,
(I-2) dry-etching the template by using the inorganic particles as an etching mask, to form convexes on the template,
(I-3) forming a coating film for an epitaxial growth mask on the template,
(I-4) removing the inorganic particles to form an exposed surface of the template,
(I-5) growing a group III-V nitride semiconductor on the exposed surface of the template, and
(I-6) separating the group III-V nitride semiconductor from the template.

2. A method for producing a group III-V nitride semiconductor substrate comprising the steps of (II-1) to (II-7):
(II-1) placing inorganic particles on a template,
(II-2) dry-etching the template by using the inorganic particles as an etching mask, to form convexes on the template,
(II-3) removing the inorganic particles,
(II-4) forming a coating film for an epitaxial growth mask on the template,
(II-5) removing the coating film at the top of the convexes, to form an exposed surface of the template,
(II-6) growing a group III-V nitride semiconductor on the exposed surface of the template, and
(II-7) separating the group III-V nitride semiconductor from the template.

3. The method according to claim 1, wherein inorganic particles are composed of at least one selected from the group consisting of oxides, nitrides, carbides, borides, sulfides, selenides and metals.

4. The method according to claim 3, wherein the oxide is at least one selected from the group consisting of silica, alumina, zirconia, titania, ceria, zinc oxide, tin oxide and yttrium aluminum garnet.

5. The method according to claim 1, wherein the inorganic particle has a shape of sphere, plate, needle or has no regular shape.

6. The method according to claim 1, wherein in the step (I-5) or the step (II-6), a void is formed between the template and the group III-V nitride semiconductor.

7. The method according to claim 1, wherein in the step (I-6) or the step (II-7), the separation is carried out by a method of mechanically peeling off the template from the group III-V nitride semiconductor by applied stress.

8. The method according to claim 7, wherein the separation is carried out by applying internal stress or external stress.

9. The method according to claim 8, wherein the separation is carried out by a method of spontaneously peeling off the template by stress based on the difference in thermal expansion coefficient between the group III-V nitride semiconductor and the template.
